(19) United States
(12) Patent Application Publication
(10) Pub. No.: US 2011/0056830 A1
(43) Pub. Date: Mar. 10, 2011

(54) SPUTTERING DEPOSITION APPARATUS

(75) Inventors: Chung-Pei Wang, Tu-Cheng (TW); Chia-Ying Wu, Tu-Cheng (TW)

(73) Assignee: HON HAI PRECISION INDUSTRY CO., LTD., Tu-Cheng (TW)

(21) Appl. No.: 12/766,904

(22) Filed: Apr. 25, 2010

(30) Foreign Application Priority Data
Sep. 9, 2009 (CN) 200910306812.8

(51) Int. Cl. C23C 14/34

(52) U.S. Cl. 204/298.25; 204/298.02

(57) ABSTRACT

A sputtering type deposition apparatus includes a chamber device and a target. The chamber device defines an access chamber, a first entrance from exterior to the access chamber, a depositing chamber, and a second entrance from the access chamber to the depositing chamber. The chamber device includes an access door, a separating door, and a carrier. The access door is disposed at the first entrance and configured to open or close the first entrance. The separating door is disposed at the second entrance and configured to open or close the second entrance. The carrier is disposed in the access chamber and configured to carry a substrate from the access chamber to the depositing chamber. The target is received in the depositing chamber.

### BACKGROUND

1. Technical Field

The present disclosure relates to film deposition apparatuses and, particularly, to a sputtering type deposition apparatus.

2. Description of Related Art

Generally, to deposit a thin film on a substrate by sputtering of a target, the following steps are required. First, the substrate and the target are placed in a chamber. Then, the chamber is vacuumized. A sputtering gas is introduced into the vacuumized chamber and ionized and accelerated to bombard the target. The target is caused to sputter to deposit the thin film on the substrate by the bombardment of the ionized sputtering gas. After the sputtering deposition, the substrate is taken out of the chamber. As such, the chamber needs to be vacuumized prior to every time of sputtering deposition, reducing convenience and efficiency while increasing cost. In addition, the target may be oxidized when the chamber device is opened, reducing purity of the target.

Therefore, it is desirable to provide a sputtering deposition apparatus, which can overcome the abovementioned shortcomings.

### BRIEF DESCRIPTION OF THE DRAWINGS

Many aspects of the present sputtering deposition apparatus should be better understood with reference to the following drawings. The components in the drawings are not necessarily drawn to scale, the emphasis instead being placed upon clearly illustrating the principles of the present sputtering deposition apparatus. Moreover, in the drawings, like reference numerals designate corresponding parts throughout the several views.

FIGS. 1-3 are schematic views of a sputtering deposition apparatus in different operating states respectively, according to an exemplary embodiment.

### DETAILED DESCRIPTION

Embodiments of the present sputtering deposition apparatus will now be described in detail with reference to the drawings.

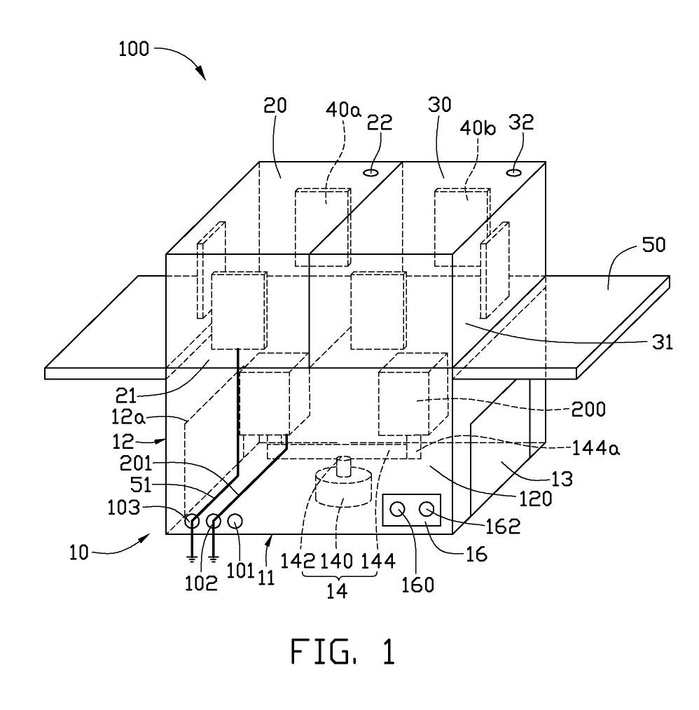

Referring to FIG. 1, a sputtering deposition apparatus 100, according to an exemplary embodiment, includes a chamber device 10 and a number of first targets 40a and second targets 40b.

The chamber device 10 is substantially a cubic shell and defines an access chamber 120 and two depositing chambers 20 and 30 therein.

In this embodiment, the access chamber 120 is cubic and formed at a bottom portion of the chamber device 10. Accordingly, the chamber device 10 forms a substantially rectangular bottom board 11 and sidewalls 12 uprightly extending upwards from edges of the bottom board 11. The access chamber 10 is bounded by the bottom board 11 and the sidewalls 12. Left and right sidewalls 12 define two entrances 12a respectively. The chamber device 10 includes two access doors 13. The access doors 13 are disposed at the entrances 12a respectively and constructed to open or hermetically close the entrances 12a respectively. A front sidewall 12 defines an outlet 101 and two wire holes 102 and 103 through a left bottom portion thereof. The chamber device 10 also includes a control panel 16. The control panel 16 is mounted to a right bottom portion of the outer surface of the front sidewall 12. The control panel 16 includes key buttons 160 and 162.

The depositing chambers 20 and 30 are substantially similar to each other in shape (cubic) and size but respectively positioned at a top left portion and a top right portion of the chamber device 10. The chamber device 10 defines two chamber entrances 21 and 31 from the access chamber 120 to the depositing chambers 20 and 30 respectively. The chamber device 10 also defines two second inlets 22 and 32 that communicate with the depositing chambers 20 and 30 respectively.

The chamber device 10 further includes a separating door 50. The separating door 50 is disposed at the chamber entrances 21 and 31 and constructed to open or hermetically close the chamber entrances 21 and 31. As such, when the separating door 50 is opened, the depositing chambers 20 and 30 communicate with the access chamber 120. When the separating door 50 is closed, the chamber entrances 21 and 31 are closed. The depositing chambers 20 and 30 and the access chamber 120 are hermetically separated from each other.

The chamber device 10 also includes a carrier 14 disposed within the access chamber 120, substantially on the center of the bottom board 11. The carrier 14 includes a motor 140, a cylinder 142, and a supporting plate 144. The motor 140 is disposed on the bottom board 11, substantially at the center thereof. The cylinder 142 is disposed on the motor 140. The supporting plate 144 is disposed on the cylinder 142. In particular, the supporting plate 144 is an elongated plate and a central portion thereof is connected to the cylinder 142. Two holding rods 144a extend upwards from two distal ends of the supporting plate 144 and configured for holding two substrates 200. The motor 140 is configured to rotate the cylinder 142. The cylinder 142 is configured to lift or lower the supporting plate 144.

The targets 40a and 40b are received within the depositing chambers 20 and 30 respectively. The targets 40a and 40b are typically different materials for depositing different layers of the thin film on the substrates 200 (see below). Also, the targets 40a and 40b can be of the same material.

In operation, the access doors 13 are closed and the separating door 50 is opened. The chamber device 10 is connected to an air pump (not shown) via the outlet 101 and the communicated chambers 120, 20, and 30 are vacuumized by the air pump. Then, the separating door 50 is closed and the doors 13 are opened. The substrates 200 are placed in the access chambers 120 and held by the holding rods 144a. The substrates 200 and the targets 40a and 40b are grounded via wires 102 and 103 that run through the wire holes 102 and 103 respectively. The access chamber 120 is vacuumized again.

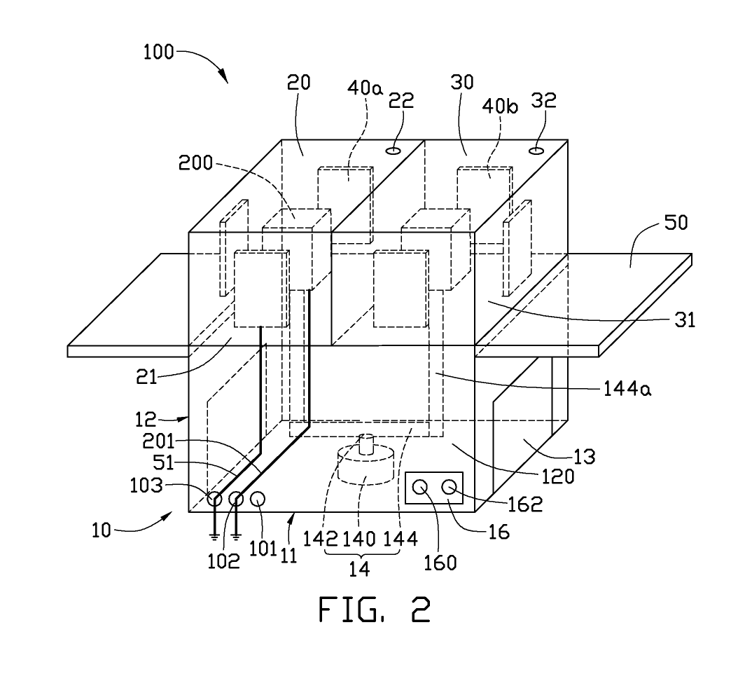

Then, referring to FIG. 2, the separating door 50 is opened. The cylinder 142 lifts the substrates 200 to the depositing chambers 20 and 30 respectively. The chamber device 10 is connected to sputtering gas sources (not shown) via the inlets 22 and 32. Then, sputtering gases are introduced into the depositing chambers 20 and 30 and are ionized and accelerated to bombard the targets 40a and 40b. The targets 40a and 40b start to sputter to deposit layers of the thin film on the substrates 200.

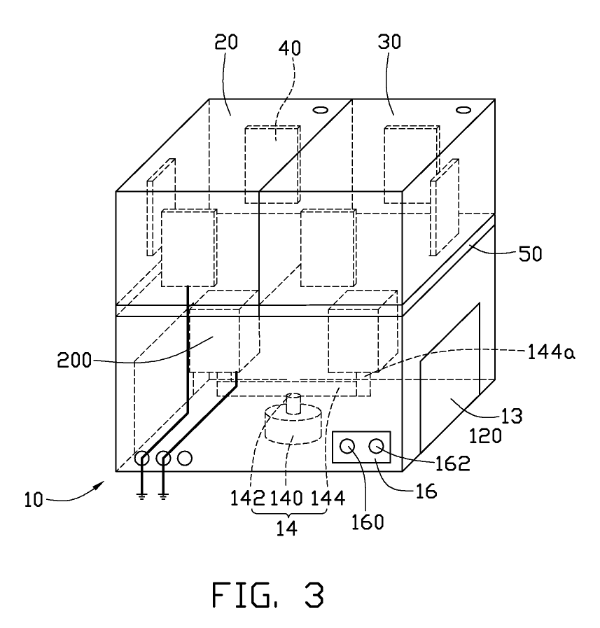

Referring to FIG. 3, after the sputtering deposition has been finished, the cylinder 142 lowers the substrates 200 to the access chamber 120. The motor 140 rotate the supporting plate 144 180 degrees. Then, the cylinder 142 lifts the substrates again to exchange the substrates 200 between the depositing chambers 20 and 30. As such, the sputtering deposition apparatus 100 can deposit another layer of the thin film on the substrates 200.

The access doors 13, the carrier 14, the separating door 50, the air pump, and the sputtering gas sources can be connected to the control panel 16 and controlled by the control panel 16. Alternatively, the access doors 13 and the separating door 50 can be manually operated.

It is noteworthy that the chamber device 10 is not limited to this embodiment. For example, the shape of the chamber device 10 can be other than a cubic shell. Only one or more than two depositing chambers can be deployed instead. Of course, if only one depositing chamber is employed the motor 140 can be omitted. If more than two depositing chambers are employed, the depositing chambers can be arranged at an upper portion of the chamber device in a manner that facilitates exchanging substrates 200 among the depositing chambers. As such, deposition of more than two layers of thin film can be carried out at a time. Also, one or more than two entrances and access doors can be employed depending on requirements.

It will be understood that the above particular embodiments and methods are shown and described by way of illustration only. The principles and the features of the present disclosure may be employed in various and numerous embodiment thereof without departing from the scope of the disclosure as claimed. The above-described embodiments illustrate the scope of the disclosure but do not restrict the scope of the disclosure.

What is claimed is:

1. A sputtering apparatus comprising:
a chamber device defining an access chamber, a first entrance from an exterior to the access chamber, a depositing chamber, and a second entrance from the access chamber to the depositing chamber; the chamber device comprising an access door, a separating door, and a carrier; the access door being disposed at the first entrance and configured to open or hermetically close the first entrance; the separating door being disposed at the second entrance and configured to open or hermetically close the second entrance; the carrier being disposed in the access chamber and configured to carry a substrate to move between the access chamber to the depositing chamber; and
a target received in the depositing chamber.

2. The sputtering deposition apparatus of claim 1, wherein the chamber device defines an outlet communicating with the access chamber and is connected to an air pump through the outlet.

3. The sputtering deposition apparatus of claim 1, wherein the chamber device includes two wire holes and two wires, the substrate and the target being grounded via the wires running through the respective wire holes.

4. The sputtering deposition apparatus of claim 1, wherein the chamber device defines an inlet communicating with the depositing chamber for connection to a sputtering gas source through the inlet.

5. The sputtering deposition apparatus of claim 1, wherein the chamber device comprises a control panel configured to control movement of the carrier.

6. The sputtering deposition apparatus of claim 1, wherein the chamber device comprises a control panel configured for controlling opening and closing of the access door and the separating door.

7. The sputtering deposition apparatus of claim 1, wherein the carrier comprises a cylinder configured to drive the substrate to linearly move between the access chamber and the depositing chamber.

8. The sputtering deposition apparatus of claim 1, further comprising another target, wherein the chamber device further defines another depositing chamber, the targets being disposed within the depositing chambers respectively, the depositing chambers being arranged at the same side of the access chamber, the carrier being configured to carry two substrates to move to between the access chamber and the depositing chambers and switch the substrates between the deposition chambers.

9. The sputtering deposition apparatus of claim 9, wherein the carrier comprises a motor, a cylinder, and a supporting plate, the cylinder being disposed on the motor, the supporting plate being coupled to the cylinder, the substrates being held by two distal ends of the supporting plate, the cylinder being configured to move the substrate between the access chamber and the depositing chambers, the motor being configured to switch the substrate between the depositing chambers.

10. The sputtering deposition apparatus of claim 8, wherein the targets are comprised of the same material.

11. The sputtering deposition apparatus of claim 8, wherein the targets are comprised of different materials.
